(19) United States
(12) Patent Application Publication
(10) Pub. No.: US 2026/0107480 A1
(43) Pub. Date: Apr. 16, 2026

(54) THERMAL MITIGATION FOR MULTI-CHIP MEMORY SYSTEMS

(71) Applicant: Micron Technology, Inc., Boise, ID (US)

(72) Inventors: Ramesh Nallavelli, Hyderabad (IN); Suresh Kumar Upadhyayula, San Jose, CA (US)

(21) Appl. No.: 19/345,949

(22) Filed: Sep. 30, 2025

Related U.S. Application Data
(60) Provisional application No. 63/707,614, filed on Oct. 15, 2024.

(51) Int. Cl. H10B 80/00; H01L 25/00; H01L 25/065; H01L 25/18

(52) U.S. Cl. CPC H10B 80/00; H10W 90/00; H10W 90/24; H10W 90/288; H10W 90/291

(57) ABSTRACT

Methods, systems, and devices for thermal mitigation for multi-chip memory systems are described. For example, the described techniques may support one or more heat transfer components to contact one or more controller dies of a multi-chip package (MCP) that also includes one or more memory array dies. For example, a layer of a mold compound material may be removed to expose a top surface of a controller die, and a heat transfer component may be attached in contact with the top surface of the controller die. Additionally, or alternatively, a heat transfer component may be attached to a top surface of a controller die prior to forming a mold compound material. The mold compound material may be formed over the controller die and heat transfer component, and a portion of the mold compound material may be removed to expose a top surface of the heat transfer component.

### CROSS REFERENCE

The present Application for Patent claims priority to U.S. Patent Application Ser. No. 63/707,614 by Nallavelli et al., entitled “THERMAL MITIGATION FOR MULTI-CHIP MEMORY SYSTEMS,” filed Oct. 15, 2024, which is assigned to the assignee hereof, and which is expressly incorporated by reference in its entirety herein.

### TECHNICAL FIELD

The following relates to one or more systems for memory, including thermal mitigation for multi-chip memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

In some implementations, a multi-chip package (MCP) may include a memory controller component and a set of one or more memory array components. The memory controller component may generate heat, which may increase a temperature of the MCP. In some examples, the MCP may have a threshold temperature (e.g., an operating temperature limit) at which the MCP may operate.

### BRIEF DESCRIPTION OF THE DRAWINGS

FIG. 1 shows an example of a system that supports thermal mitigation for multi-chip memory systems in accordance with examples as disclosed herein.

FIGS. 2A and 2B shows an example of a system that supports thermal mitigation for multi-chip memory systems in accordance with examples as disclosed herein.

FIGS. 3A and 3B shows an example of a system that supports thermal mitigation for multi-chip memory systems in accordance with examples as disclosed herein.

FIGS. 4 and 5 show flowcharts illustrating a method or methods that support thermal mitigation for multi-chip memory systems in accordance with examples as disclosed herein.

### DETAILED DESCRIPTION

A multi-chip package (MCP) may, in some implementations, include a memory controller component and one or more memory array components (e.g., coupled with a common substrate). In some examples, a memory controller component may generate a relatively large amount of heat, which may increase a temperature of an MCP, or locations thereof (e.g., hot spots). In some examples, an MCP may have a threshold temperature (e.g., an operating temperature limit) at which the MCP may operate. For example, operational performance or integrity of an MCP may degrade when the temperature of the MCP is above the threshold temperature. Heat generated by a memory controller component may cause the temperature of a MCP to rise above a threshold temperature, which may degrade performance or reduce a lifespan of the MCP.

In accordance with examples as disclosed herein, one or more heat transfer components (e.g., a thermal interface material (TIM), a die attach film (DAF), a spacer) may be configured to be in contact with a memory controller component of an MCP, and separate from one or more array components. For example, a layer of a mold compound material (e.g., an epoxy mold compound (EMC)) may be removed to expose a top surface of the memory controller component, and a TIM may be located in contact with the top surface of the memory controller component. A spacer may be attached to a top surface of the TIM to reach a same height above a substrate as a non-removed portion of the mold compound material (e.g., a portion formed over the one or more memory array components). Additionally, or alternatively, a TIM and a spacer may be attached to a top surface of the memory controller component prior to forming a mold compound material. The mold compound material may be formed over the memory controller, TIM, and spacer (e.g., and over a set of one or more memory array components), and a portion of the mold compound material may be removed to expose a top surface of the spacer. Such techniques may improve heat dissipation in the MCP, which may improve performance and/or lengthen a lifespan of the MCP.

In addition to applicability in memory systems as described herein, techniques for thermal mitigation may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may use with relatively more processing to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing a temperature of a memory controller in a MCP, which may improve thermal performance and package reliability, among other benefits.

Features of the disclosure are illustrated and described in the context of systems, devices, and circuits. Features of the disclosure are further illustrated and described in the context of systems and flowcharts.

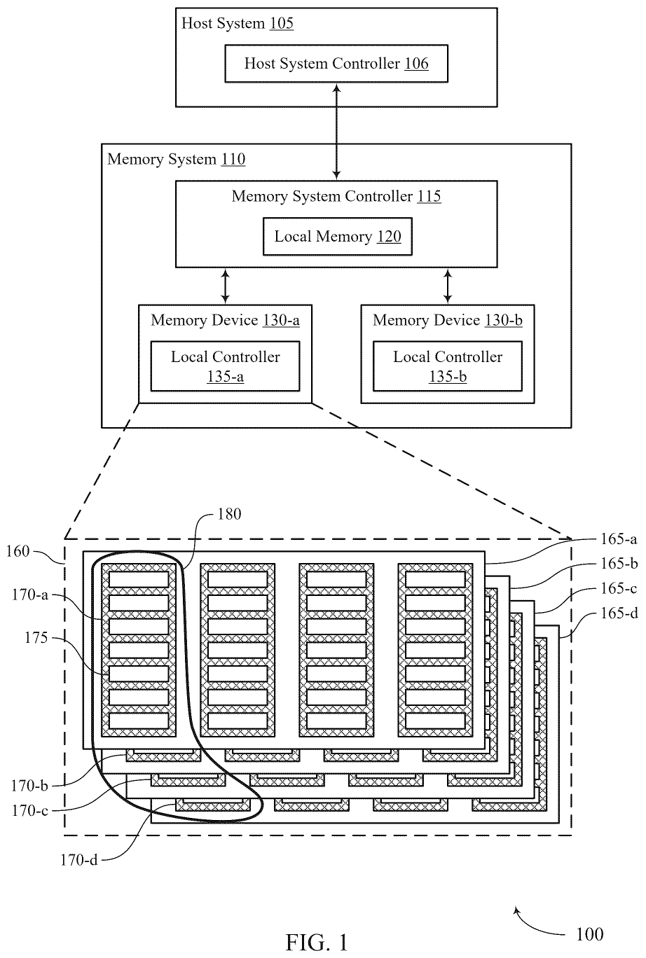

FIG. 1 shows an example of a system 100 that supports thermal mitigation for multi-chip memory systems in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some examples, a memory system 110 or a memory device 130 may be implemented as an MCP that includes one or more first semiconductor dies that include one or more memory arrays (e.g., one or more planes 165) and one or more second semiconductor dies that include circuitry (e.g., control circuitry) operable to access the one or more memory arrays (e.g., circuitry of a local controller 135, circuitry of a memory system controller 115, or a combination thereof). The one or more second semiconductor dies may have a relatively higher temperature than some other components of the memory system 110 or memory device 130 (e.g., due to relatively higher power flux in locations on the controller die such as a low dropout (LDO) component or an analog subsystem). For example, power improvements and package size reduction of an MCP may result in a relatively large amount of heat generated by a controller die. In some examples, heat generated by a controller die may cause the temperature of a MCP to exceed an operating temperature (e.g., a maximum operating temperature limit), which may degrade performance of the MCP. Additionally, an encapsulation material (e.g., a mold compound material, an EMC) with relatively low thermal conductivity in a heat dissipation path of the controller die may add additional thermal resistance and therefore reduce an amount of heat dissipated from a controller die.

In some examples, the memory system 110 or memory device 130 implemented in an MCP may include one or more heat transfer components (e.g., a heat spreader, a TIM, a DAF, a spacer) that may reduce a thermal resistance from one or more controller dies to a case surface of the MCP. For example, the heat transfer components may form a heat dissipation path (e.g., a heat transfer path, a heat rejection path, a path to a heat sink) to allow heat to dissipate from the controller die of the MCP. For example, a portion of a mold compound material (e.g., the EMC) may include an opening through which heat transfer components may be in contact with a controller die. For example, a portion of the EMC may be removed or formed such that the controller die is exposed, and a material with a relatively higher thermal conductivity than the EMC may be bonded to the controller die. Accordingly, heat may exit the controller die (e.g., to a package surface or case) through the heat transfer components, which may result in a reduced temperature and relatively more uniform heat distribution of the controller die as compared to packages without the heat transfer components.

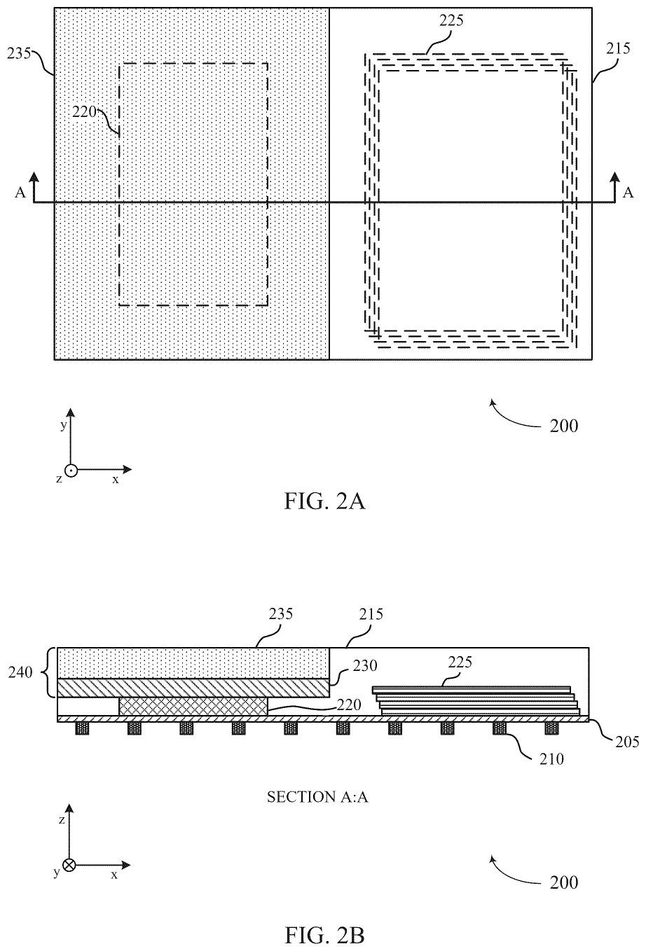

FIGS. 2A and 2B show an example of a system 200 that supports thermal mitigation for multi-chip memory systems in accordance with examples as disclosed herein. A system 200 (e.g., a semiconductor system, a semiconductor device, an MCP, a memory system, an mNAND package) may implement or may be implemented by aspects of a system 100. For example, a system 200 may be an example of a memory system 110 or a memory device 140. FIG. 2A may illustrate a top view of a system 200, and FIG. 2B may illustrate a cross-sectional view of the system 200 (e.g., relative to a cut plane A-A), and aspects of the system 200 may be described relative to an x-direction, a y-direction, and a z-direction of the illustrated coordinate system.

A system 200 may include one or more dies 225 (e.g., first semiconductor die(s), memory array die(s), a single die, one or more stacks of multiple dies) that are bonded with (e.g., coupled with, fused with, soldered with) a first location of a surface of a substrate 205 (e.g., in an xy-plane). The die(s) 225 may include one or more memory arrays, such as one or more planes 165 (e.g., a NAND stack of one or more NAND memory arrays). In some examples (e.g., in which the system 200 is an example of a memory system 110), one or more of the die(s) 225 may implement a respective memory device 130 (e.g., including a respective local controller 135).

A system 200 may also include one or more dies 220 (e.g., second semiconductor die(s), controller die(s), a single die, one or more stacks of multiple dies) that are bonded with a second location of the surface of the substrate 205 (e.g., in the xy-plane). The die(s) 220 may include circuitry operable to access the memory array(s) of the die(s) 225. In some examples (e.g., in which the system 200 is an example of a memory system 110), one or more of the die(s) 220 may implement a memory system controller 115. In some other examples (e.g., in which the system 200 is an example of a memory device 130), one or more of the die(s) 220 may implement a local controller 135. In various examples, a top surface of the die(s) 220 may be below (e.g., along the z-direction) a top surface of the die(s) 225, above a top surface of the die(s) 225, or coplanar with a top surface of the die(s) 225.

A substrate 205 may be an organic substrate, such as a printed circuit board (PCB), or may be another type of substrate (e.g., a semiconductor substrate, a semiconductor die that is larger in an xy-plane than the die(s) 220 and die(s) 225). The substrate 205 may include various conductor arrangements such that circuitry of the die(s) 220 is coupled with the memory array(s) of the die(s) 225 via the substrate 205. A substrate 205 may also include contacts 210 (e.g., electrical contacts, solder pads, solder balls) on a surface opposite from (e.g., along the z-direction) a surface upon which the die(s) 220 and die(s) 225 are bonded. Contacts 210 may be coupled with circuitry of the die(s) 220, circuitry of the die(s) 225, or both.

A system 200 may also include a mold compound material 215 (e.g., EMC, formed over the substrate 205). In some examples, a mold compound material 215 may cover the die(s) 225 (e.g., with the top of the die(s) 225 being below a surface of the mold compound material 215 along the z-direction). Additionally, or alternatively, a mold compound material 215 may be formed around (e.g., in contact with, along, in an xy-plane) one or more sides of the die(s) 220, one or more sides of the die(s) 225, or both (e.g., may surround the die(s) 220 and the die(s) 225). A mold compound material 215 may include an opening (e.g., in an xy-plane, at distance along the z-direction from the substrate 205) through which a surface of the die(s) 220 (e.g., a surface in an xy-plane opposite from the substrate 205) is exposed. For example, a portion of the mold compound material 215 over the first location may extend with a first height above the substrate 205 (e.g., along the z-direction) that is higher than the die(s) 225, and portion of the mold compound material 215 that surrounds one or more sides of the die(s) 220 (e.g., a height of the opening in the mold compound material 215) may extend with a second height above the substrate 205 that is less than the first height (e.g., in a stepped configuration, such that the surface of the die(s) 220 is exposed via the opening in the mold compound material 215).

A system 200 may include one or more heat transfer components 240 (e.g., a set of one or more heat transfer components, a stack of heat transfer components) bonded with the die(s) 220 (e.g., on the exposed side of the die(s) 220 opposite the substrate 205 along the z-direction). For example, the heat transfer component(s) 240 may be bonded to the die(s) 220 (e.g., a top die 220 of one or more stacks of dies 220) through the opening in the mold compound material 215, which may be supported by a TIM 230 (e.g., a DAF, a thermal paste, a conformal thermal interface material). In the illustrated example, the heat transfer component(s) 240 may include a TIM 230 and a spacer 235. A spacer 235 may include a material with relatively high thermal conductivity (e.g., compared to a mold compound material 215), such as aluminum, copper, graphite, magnesium, silicon, silver, or any combination thereof. A spacer 235 may extend to a height above the surface of the substrate 205 (e.g., along the z-direction) that is coplanar with the mold compound material 215 over the die(s) 225 (e.g., above a top surface of the die(s) 225). Such an implementation may support the die(s) 225 being embedded in the mold compound material 215, which may support a favorable heat dissipation path for the die(s) 220, or a more-uniform temperature distribution across the die(s) 220 (e.g., in an xy-plane), or both. In some examples, heat transfer component(s) 240 may be configured to support a heat dissipation path (e.g., a heat rejection path) from the die(s) 220 through the opening in the mold compound material 215 (e.g., along the z-direction). For example, a heat sink (not shown) may be bonded with the spacer 235, the mold compound material 215, or both (e.g., along a top surface of the system 200) such that the heat dissipation path may enable heat to flow from the die(s) 220 to the heat sink.

In some examples, the heat transfer component(s) 240 may be relatively larger than the die(s) 220 (e.g., along one or more directions in an xy-plane). For example, at least a portion of the heat transfer component(s) 240 may extend beyond the die(s) 220 along the x-direction, along the y-direction, or both. Additionally, or alternatively, the size of the heat transfer component(s) 240 may be configured such that a surface of a spacer 235 (e.g., opposite the die(s) 220, opposite the substrate 205) is coplanar with the mold compound material 215 over the die(s) 225. For example, heat transfer component(s) 240 may be configured with a size (e.g., a length, a width, a thickness) that balances performance with overall size of a system 200, costs for manufacturing a system, and other considerations.

A manufacturing process to form a system 200 may include bonding die(s) 225 to a first location on a surface of the substrate 205 and bonding die(s) 220 to a second location on the surface of the substrate 205. In some examples, bonding die(s) 220, bonding die(s) 225, or both to the substrate 205 may involve a molded underfill (MUF) operation, in which a film of material is placed between the respective surfaces to be bonded and, in some examples, the film may have dimensions (e.g., precut dimensions, along the x-direction, along the y-direction, or both) that are smaller than the surface of a die to be bonded. Accordingly, a gap may be present in at least some locations between the substrate 205 and the die(s) that are bonded to the substrate 205, which may or may not be related to the implementation of an MUF operation. The manufacturing process may also include forming the mold compound material 215 over the surface of the substrate 205.

In some implementations, forming the mold compound material 215 may include forming an opening in the mold compound material 215 that exposes a surface of the die(s) 220. For example, forming the mold compound material 215 may include forming the mold compound material 215 to a first height above the die(s) 225 in the first location (e.g., surrounding one or more sides of the die(s) 225, covering a surface of the die(s) 225 opposite the substrate 205) and forming the mold compound material 215 to a second height in the second location such that the second height results in a surface of the die(s) 220 opposite the substrate 205 being exposed via an opening. In some examples, the mold compound material 215 may be formed to a height that is coplanar with or shorter than a height of the die(s) 220 such that the surface of the die(s) 220 opposite from the substrate 205 is exposed. Additionally, or alternatively, the manufacturing process may include removing (e.g., grinding, planarizing) a portion of the mold compound material 215 to form the opening to expose the surface of the die(s) 220. In some examples, the mold compound material 215 may be formed to the first height in the first location and to the second height in the second location using a mold (e.g., a stepped mold).

Additionally, or alternatively, forming the mold compound material 215 may include forming the mold compound material 215 to the first height over both the die(s) 225 and the die(s) 220. In such examples, forming the mold compound material 215 may include removing (e.g., grinding, planarizing) a portion of the mold compound material 215 in the second location above the die(s) 220 to expose the surface of the die(s) 220 opposite the substrate 205. That is, the portion of the mold compound material 215 over the second location on the substrate 205 (e.g., above the die(s) 220) may be removed to form the opening that exposes the surface of the die(s) 220.

The manufacturing process may also include bonding the heat transfer component(s) 240 with the exposed surface of the die(s) 220. For example, the manufacturing process may include bonding a TIM 230 with the exposed surface of the die(s) 220, and bonding the spacer 235 with a surface of the TIM 230 that is opposite from the die(s) 220. In some examples,

In some examples, bonding the heat transfer component(s) 240 to the die(s) 220 may form a heat dissipation path enables heat to dissipate more easily from the die(s) 220 through the opening in the mold compound material 215. In some examples, the heat dissipation path may cause heat to dissipate from the die(s) 220 to a heat sink (not shown). For example, the manufacturing process may include bonding a heat sink to a surface of the spacer 235, the mold compound material 215, or both.

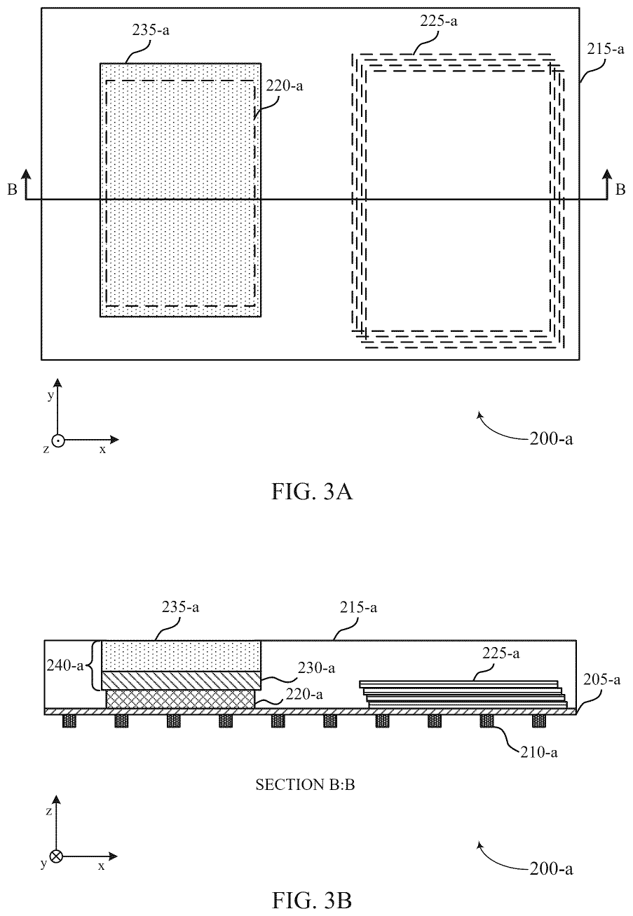

FIGS. 3A and 3B show an example of a system 200-a that supports thermal mitigation for multi-chip memory systems in accordance with examples as disclosed herein. A system 200-a may implement or may be implemented by aspects of a system 100 or a system 200. For example, a system 200-a may be an example of a memory system 110 or a memory device 140. FIG. 3A may illustrate a top view of a system 200-a, and FIG. 3B may illustrate a cross-sectional view of the system 200-a (e.g., relative to a cut plane B-B), and aspects of the system 200-a may be described relative to an x-direction, a y-direction, and a z-direction of the illustrated coordinate system.

A system 200-a may include components that are similar to those of a system 200, but with some different configuration aspects. For example, a system 200-a may include one or more dies(s) 225-a that are bonded with a first location of a surface of a substrate 205-a, and one or more dies(s) 220-a that are bonded with a second location of the surface of a substrate 205-a. A substrate 205-a may include contacts 210-a on a surface opposite from a surface upon which the die(s) 220-a and die(s) 225-a are bonded, and the contacts 210-a may be coupled with circuitry of the die(s) 220-a, circuitry of the die(s) 225-a, or both. In some examples (e.g., in which the system 200-a is an example of a memory system 110), one or more of the die(s) 225-a may implement a respective memory device 130 (e.g., including a respective local controller 135), and one or more of the die(s) 220-a may implement a memory system controller 115. In some other examples (e.g., in which the system 200-a is an example of a memory device 130), one or more of the die(s) 220-a may implement a local controller 135.

A system 200-a may also include a mold compound material 215-a, which may cover the die(s) 225-a. Additionally, or alternatively, a mold compound material 215-a may be formed around one or more sides of the die(s) 220-a, one or more sides of the die(s) 225-a, or both. A mold compound material 215-a may include an opening through which a surface of one or more heat transfer components 240-a is exposed. The mold compound material 215-a may extend to a height above the substrate that is higher than the die(s) 225-a and the die(s) 220-a, which may be equal to (e.g., coplanar with) a height of the heat transfer component(s) 240-a (e.g., such that the surface of the heat transfer component(s) 240-a is exposed via the opening in the mold compound material 215-a).

A system 200-a may include one or more heat transfer components 240-a bonded with the die(s) 220-a. In the illustrated example, the heat transfer component(s) 240-a may include a TIM 230-a and a spacer 235-a (e.g., a material with relatively high thermal conductivity, such as aluminum, copper, graphite, magnesium, silicon, silver, or any combination thereof). A spacer 235-a may extend to a height above the surface of the substrate 205-a that is coplanar with the mold compound material 215-a over the die(s) 225-a. Such an implementation may support the die(s) 225-a being embedded in the mold compound material 215-a, which may support a favorable heat dissipation path for the die(s) 220-a, or a more-uniform temperature distribution across the die(s) 220-a, or both. Heat transfer component(s) 240-a may be configured to support a heat dissipation path from the die(s) 220-a through the opening in the mold compound material 215-a. For example, a heat sink (not shown) may be bonded with the spacer 235-a, the mold compound material 215-a, or both (e.g., along a top surface of the system 200-a) such that the heat dissipation path may enable heat to flow from the die(s) 220-a to the heat sink.

In some examples, the heat transfer component(s) 240-a may be relatively larger than the die(s) 220-a (e.g., may extend beyond the die(s) 220-a along the x-direction, along the y-direction, or both). Additionally, or alternatively, the size of the heat transfer component(s) 240-a may be configured such that a surface of a spacer 235-a is coplanar with the mold compound material 215-a over the die(s) 225-a. For example, heat transfer component(s) 240-a may be configured with a size (e.g., a length, a width, a thickness) that balances performance with overall size of a system 200-a, costs for manufacturing a system, and other considerations.

In some examples, a system 200-a may be formed with a different manufacturing process than forming a system 200. For example, a manufacturing process to form a system 200-a may include bonding die(s) 225-a to a first location on a surface of the substrate 205-a and bonding die(s) 220-a to a second location on the surface of the substrate 205-a. In some examples, bonding die(s) 220-a, bonding die(s) 225-a, or both to the substrate 205-a may involve a MUF operation, in which a film of material is placed between the respective surfaces to be bonded and, in some examples, the film may have dimensions (e.g., precut dimensions, along the x-direction, along the y-direction, or both) that are smaller than the surface of a die to be bonded. Accordingly, a gap may be present in at least some locations between the substrate 205-a and the die(s) that are bonded to the substrate 205-a, which may or may not be related to the implementation of an MUF operation.

The manufacturing process may also include bonding heat transfer component(s) 240-a with a surface of the die(s) 220-a opposite the substrate 205-a. For example, the manufacturing process may include bonding a TIM 230-a with the surface of the die(s) 220-a, and bonding a spacer 235-a with a surface of the TIM 230-a that is opposite the die(s) 220-a. The manufacturing process may also include forming the mold compound material 215-a over the surface of the substrate 205-a (e.g., after bonding of the dies 225-a, the dies 220-a, and heat transfer component(s) 240-a).

In some implementations, forming the mold compound material 215-a may include forming an opening in the mold compound material 215-a that exposes a surface of the heat transfer component(s) 240-a opposite the die(s) 220-a. For example, forming the mold compound material 215-a may include forming the mold compound material 215-a to a first height (e.g., above the die(s) 225-a). The mold compound material 215-a may be formed to surround one or more sides of the die(s) 225-a and the die(s) 220-a and to cover a surface of the die(s) 225-a opposite from the substrate 205-a.

In some examples, the mold compound material 215-a may be formed to a height that is coplanar with or shorter than a height of the heat transfer component(s) 240-a such that the surface of the heat transfer component(s) 240-a opposite the die(s) 220-a is exposed. In some examples, the manufacturing process may include removing (e.g., grinding, planarizing) a portion of the mold compound material 215-a to form the opening to expose the surface of the heat transfer component(s) 240-a. In some examples, the mold compound material 215-a may be formed using a mold.

In some other examples, forming the mold compound material 215-a may include forming the mold compound material 215-a to a height over the die(s) 225-a and the heat transfer component(s) 240-a. In such examples, forming the mold compound material 215-a may include removing (e.g., grinding, planarizing) a portion of the mold compound material 215-a in the second location above the heat transfer component(s) 240-a to expose the surface of the heat transfer component(s) 240-a opposite the die(s) 220-a. That is, the portion of the mold compound material 215-a over the second location on the substrate 205-a (e.g., above the heat transfer component(s) 240-a) may be removed to form the opening that exposes the surface of the heat transfer component(s) 240-a.

In some examples, the heat transfer component(s) 240-a may form a heat dissipation path that enables heat to dissipate more easily from the die(s) 220-a through the opening in the mold compound material 215-a. In some examples, the heat dissipation path may cause heat to dissipate from the die(s) 220-a to a heat sink (not shown). For example, the manufacturing process may include bonding a heat sink to a surface of the spacer 235-a, the mold compound material 215-a, or both.

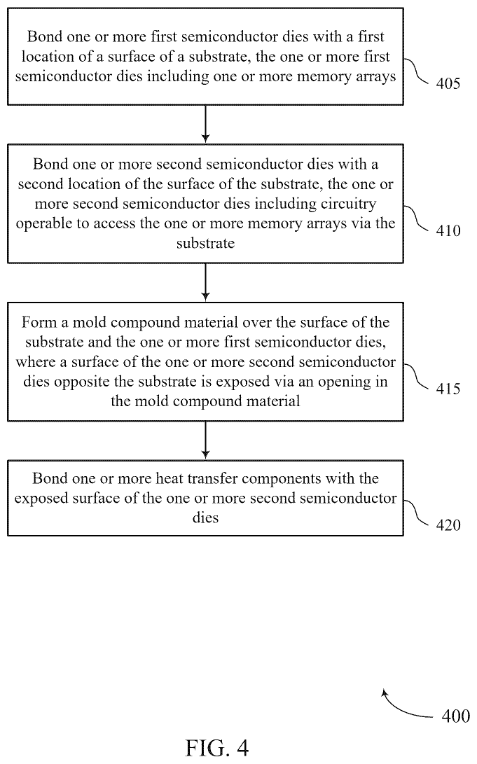

FIG. 4 shows a flowchart illustrating a method 400 that supports thermal mitigation for multi-chip memory systems in accordance with examples as disclosed herein. The operations of method 400 may be implemented by a manufacturing system or one or more controllers associated with a manufacturing system (e.g., to manufacture a system 200). In some example s, one or more controllers may execute a set of instructions to control one or more functional elements of the manufacturing system to perform the described functions.

Additionally, or alternatively, one or more controllers may perform aspects of the described functions using special-purpose hardware.

At 405, the method may include bonding one or more first semiconductor dies (e.g., die(s) 225) with a first location of a surface of a substrate (e.g., a substrate 205), the one or more first semiconductor dies including one or more memory arrays.

At 410, the method may include bonding one or more second semiconductor dies (e.g., die(s) 220) with a second location of the surface of the substrate, the one or more second semiconductor dies including circuitry operable to access the one or more memory arrays via the substrate.

At 415, the method may include forming a mold compound material (e.g., a mold compound material 215) over the surface of the substrate and the one or more first semiconductor dies, where a surface of the one or more second semiconductor dies opposite the substrate is exposed via an opening in the mold compound material.

At 420, the method may include bonding one or more heat transfer components (e.g., heat transfer component(s) 240) with the exposed surface of the one or more second semiconductor dies.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for bonding one or more first semiconductor dies with a first location of a surface of a substrate, the one or more first semiconductor dies including one or more memory arrays; bonding one or more second semiconductor dies with a second location of the surface of the substrate, the one or more second semiconductor dies including circuitry operable to access the one or more memory arrays via the substrate; forming a mold compound material over the surface of the substrate and the one or more first semiconductor dies, where a surface of the one or more second semiconductor dies opposite the substrate is exposed via an opening in the mold compound material; and bonding one or more heat transfer components with the exposed surface of the one or more second semiconductor dies.
Aspect 2: The method or apparatus of aspect 1, where forming the mold compound material includes operations, features, circuitry, logic, means, or instructions, or any combination thereof for forming the mold compound material over the surface of the one or more second semiconductor dies opposite the substrate and exposing the surface of the one or more second semiconductor dies opposite the substrate based at least in part on removing a portion of the mold compound material over the second location of the surface of the substrate to form the opening.
Aspect 3: The method or apparatus of any of aspects 1 through 2, where forming the mold compound material includes operations, features, circuitry, logic, means, or instructions, or any combination thereof for forming the mold compound material over the first location with a first height above the substrate that is above the one or more first semiconductor dies and forming the mold compound material over the second location with a second height above the substrate that is less than the first height, where the opening is associated with forming the mold compound material with the second height.
Aspect 4: The method or apparatus of any of aspects 1 through 3, where a surface of the one or more heat transfer components opposite the one or more second semiconductor dies is coplanar with a surface of the mold compound material.
Aspect 5: The method or apparatus of any of aspects 1 through 4, where bonding the one or more heat transfer components with the exposed surface of the one or more second semiconductor dies includes operations, features, circuitry, logic, means, or instructions, or any combination thereof for bonding a spacer material with the one or more second semiconductor dies via a TIM, a DAF, or both.
Aspect 6: The method or apparatus of aspect 5, where the spacer material includes aluminum, copper, graphite, magnesium, or a combination thereof.
Aspect 7: The method or apparatus of any of aspects 1 through 6, where the mold compound material is formed around one or more sides of the one or more first semiconductor dies and around one or more sides of the one or more second semiconductor dies.
Aspect 8: The method or apparatus of any of aspects 1 through 7, where at least a portion of the one or more heat transfer components extends beyond the one or more second semiconductor dies along one or more directions over the substrate.
Aspect 9: The method or apparatus of any of aspects 1 through 8, where the one or more heat transfer components are configured to support a heat dissipation path from the one or more second semiconductor dies through an opening of the mold compound material.
Aspect 10: The method or apparatus of any of aspects 1 through 9, where the one or more memory arrays include one or more NAND memory arrays and the one or more second semiconductor dies includes processing circuitry operable to access the one or more NAND memory arrays.

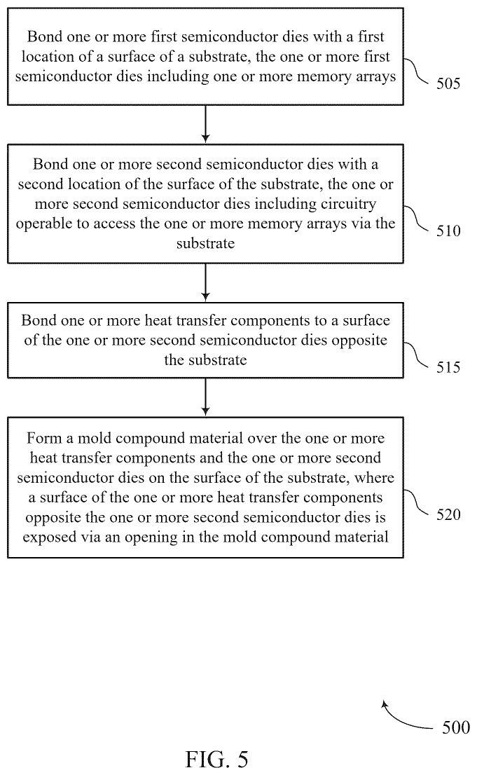

FIG. 5 shows a flowchart illustrating a method 500 that supports thermal mitigation for multi-chip memory systems in accordance with examples as disclosed herein. The operations of method 500 may be implemented by a manufacturing system or one or more controllers associated with a manufacturing system (e.g., to manufacture a system 200-a). In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include bonding one or more first semiconductor dies (e.g., die(s) 225) with a first location of a surface of a substrate (e.g., a substrate 205), the one or more first semiconductor dies including one or more memory arrays.

At 510, the method may include bonding one or more second semiconductor dies (e.g., die(s) 220) with a second location of the surface of the substrate, the one or more second semiconductor dies including circuitry operable to access the one or more memory arrays via the substrate.

At 515, the method may include bonding one or more heat transfer components (e.g., heat transfer component(s) 240) to a surface of the one or more second semiconductor dies opposite the substrate.

At 520, the method may include forming a mold compound material (e.g., a mold compound material 215) over the one or more heat transfer components and the one or more second semiconductor dies on the surface of the substrate, where a surface of the one or more heat transfer components opposite the one or more second semiconductor dies is exposed via an opening in the mold compound material.

In some examples, an apparatus (e.g., a manufacturing system) as described herein may perform a method or methods, such as the method 5000. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 11: A method or apparatus including operations, features, circuitry, logic, means, or instructions, or any combination thereof for bonding one or more first semiconductor dies with a first location of a surface of a substrate, the one or more first semiconductor dies including one or more memory arrays; bonding one or more second semiconductor dies with a second location of the surface of the substrate, the one or more second semiconductor dies including circuitry operable to access the one or more memory arrays via the substrate; bonding one or more heat transfer components to a surface of the one or more second semiconductor dies opposite the substrate; and forming a mold compound material over the one or more heat transfer components and the one or more second semiconductor dies on the surface of the substrate, where a surface of the one or more heat transfer components opposite the one or more second semiconductor dies is exposed via an opening in the mold compound material.
Aspect 12: The method or apparatus of aspect 11, where forming the mold compound material includes operations, features, circuitry, logic, means, or instructions, or any combination thereof for forming the mold compound material over the surface of the one or more heat transfer components opposite the one or more second semiconductor dies and exposing the surface of the one or more heat transfer components opposite the one or more second semiconductor dies based at least in part on removing a portion of the mold compound material over the second location of the surface of the substrate to form the opening.
Aspect 13: The method or apparatus of any of aspects 11 through 12, where a surface of the one or more heat transfer components opposite the one or more second semiconductor dies is coplanar with a surface of the mold compound material.
Aspect 14: The method or apparatus of any of aspects 11 through 13, where bonding the one or more heat transfer components with the surface of the one or more second semiconductor dies includes operations, features, circuitry, logic, means, or instructions, or any combination thereof for bonding a layer of a TIM or, a DAF, or both with the surface of the one or more second semiconductor dies and bonding a layer of a spacer material with the layer of the TIM, the DAF, or both.
Aspect 15: The method or apparatus of aspect 14, where the spacer material includes aluminum, copper, graphite, magnesium, or any combination thereof.
Aspect 16: The method or apparatus of any of aspects 11 through 15, where the mold compound material is formed around one or more sides of the one or more first semiconductor dies and around one or more sides of the one or more second semiconductor dies.
Aspect 17: The method or apparatus of any of aspects 11 through 16, where at least a portion of the one or more heat transfer components extends beyond the one or more second semiconductor dies along one or more directions over the substrate.
Aspect 18: The method or apparatus of any of aspects 11 through 17, where the one or more heat transfer components are configured to support a heat dissipation path from the one or more second semiconductor dies through an opening of the mold compound material.
Aspect 19: The method or apparatus of any of aspects 11 through 18, where the one or more memory arrays include one or more NAND memory arrays and the one or more second semiconductor dies include processing circuitry operable to access the one or more NAND memory arrays.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 20: A system, including: a substrate; one or more first semiconductor dies including one or more memory arrays, the one or more first semiconductor dies bonded with a first location of a surface of the substrate; one or more second semiconductor dies including circuitry operable to access the one or more memory arrays, the one or more second semiconductor dies bonded with a second location of the surface of the substrate and electrically coupled with the one or more first semiconductor dies via the substrate; a mold compound material formed over the substrate and covering the one or more first semiconductor dies; and one or more heat transfer components bonded with the one or more second semiconductor dies and configured to support a heat dissipation path from the one or more second semiconductor dies through an opening in the mold compound material.
Aspect 21: The system of aspect 20, where a surface of the one or more heat transfer components opposite the substrate is coplanar with a surface of the mold compound material.
Aspect 22: The system of any of aspects 20 through 21, where the one or more heat transfer components include a spacer material bonded with the one or more second semiconductor dies via a TIM, a DAF, or both.
Aspect 23: The system of aspect 22, where the spacer material includes aluminum, copper, graphite, magnesium, or a combination thereof.
Aspect 24: The system of any of aspects 20 through 23, where the mold compound material is formed around one or more sides of the one or more first semiconductor dies and around one or more sides of the one or more second semiconductor dies.
Aspect 25: The system of any of aspects 20 through 24, where the substrate includes one or more electrical contacts on a second surface of the substrate opposite the surface, the one or more electrical contacts coupled with the one or more first semiconductor dies, the one or more second semiconductor dies, or both.
Aspect 26: The system of any of aspects 20 through 25, where at least a portion of the one or more heat transfer components extends beyond the one or more second semiconductor dies along one or more directions over the substrate.
Aspect 27: The system of any of aspects 20 through 26, further including: a heat sink bonded with a surface of the mold compound material over the first location and with a surface of the one or more heat transfer components over the second location.
Aspect 28: The system of any of aspects 20 through 27, where: the one or more memory arrays include one or more NAND memory arrays; and the one or more second semiconductor dies includes processing circuitry operable to access the one or more NAND memory arrays.
Aspect 29: The system of any of aspects 20 through 28, the one or more first semiconductor dies include a stack of multiple semiconductor dies bonded with the first location of the surface of the substrate.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.”Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A system, comprising:
a substrate;
one or more first semiconductor dies comprising one or more memory arrays, the one or more first semiconductor dies bonded with a first location of a surface of the substrate;
one or more second semiconductor dies comprising circuitry operable to access the one or more memory arrays, the one or more second semiconductor dies bonded with a second location of the surface of the substrate and electrically coupled with the one or more first semiconductor dies via the substrate;
a mold compound material formed over the substrate and covering the one or more first semiconductor dies; and
one or more heat transfer components bonded with the one or more second semiconductor dies and configured to support a heat dissipation path from the one or more second semiconductor dies through an opening in the mold compound material, wherein a surface of the one or more heat transfer components opposite the substrate is coplanar with a surface of the mold compound material.

2. The system of claim 1, wherein the one or more heat transfer components comprise a spacer material bonded with the one or more second semiconductor dies via a thermal interface material, a die attach film, or both.

3. The system of claim 2, wherein the spacer material comprises aluminum, copper, graphite, magnesium, or a combination thereof.

4. The system of claim 1, wherein the mold compound material is formed around one or more sides of the one or more first semiconductor dies and around one or more sides of the one or more second semiconductor dies.

5. The system of claim 1, wherein the substrate comprises one or more electrical contacts on a second surface of the substrate opposite the surface, the one or more electrical contacts coupled with the one or more first semiconductor dies, the one or more second semiconductor dies, or both.

6. The system of claim 1, wherein at least a portion of the one or more heat transfer components extends beyond the one or more second semiconductor dies along one or more directions over the substrate.

7. The system of claim 1, further comprising:
a heat sink bonded with a surface of the mold compound material over the first location and with a surface of the one or more heat transfer components over the second location.

8. The system of claim 1, wherein:
the one or more memory arrays comprise one or more NAND memory arrays; and
the one or more second semiconductor dies comprises processing circuitry operable to access the one or more NAND memory arrays.

9. The system of claim 1, the one or more first semiconductor dies comprise a stack of multiple semiconductor dies bonded with the first location of the surface of the substrate.

10. A method, comprising:
bonding one or more first semiconductor dies with a first location of a surface of a substrate, the one or more first semiconductor dies comprising one or more memory arrays;
bonding one or more second semiconductor dies with a second location of the surface of the substrate, the one or more second semiconductor dies comprising circuitry operable to access the one or more memory arrays via the substrate;
forming a mold compound material over the surface of the substrate and the one or more first semiconductor dies, wherein a surface of the one or more second semiconductor dies opposite the substrate is exposed via an opening in the mold compound material; and
bonding one or more heat transfer components with the exposed surface of the one or more second semiconductor dies.

11. The method of claim 10, wherein forming the mold compound material comprises:
forming the mold compound material over the surface of the one or more second semiconductor dies opposite the substrate; and
exposing the surface of the one or more second semiconductor dies opposite the substrate based at least in part on removing a portion of the mold compound material over the second location of the surface of the substrate to form the opening.

12. The method of claim 10, wherein forming the mold compound material comprises:
forming the mold compound material over the first location with a first height above the substrate that is above the one or more first semiconductor dies; and
forming the mold compound material over the second location with a second height above the substrate that is less than the first height, wherein the opening is associated with forming the mold compound material with the second height.

13. The method of claim 10, wherein a surface of the one or more heat transfer components opposite the one or more second semiconductor dies is coplanar with a surface of the mold compound material.

14. The method of claim 10, wherein bonding the one or more heat transfer components with the exposed surface of the one or more second semiconductor dies comprises:
bonding a spacer material with the one or more second semiconductor dies via a thermal interface material, a die attach film, or both.

15. The method of claim 14, wherein the spacer material comprises aluminum, copper, graphite, magnesium, or a combination thereof.

16. The method of claim 10, wherein the mold compound material is formed around one or more sides of the one or more first semiconductor dies and around one or more sides of the one or more second semiconductor dies.

17. The method of claim 10, wherein at least a portion of the one or more heat transfer components extends beyond the one or more second semiconductor dies along one or more directions over the substrate.

18. The method of claim 10, wherein the one or more heat transfer components are configured to support a heat dissipation path from the one or more second semiconductor dies through an opening of the mold compound material.

19. The method of claim 10, wherein:
the one or more memory arrays comprise one or more NAND memory arrays; and
the one or more second semiconductor dies comprises processing circuitry operable to access the one or more NAND memory arrays.

20. A method, comprising:
bonding one or more first semiconductor dies with a first location of a surface of a substrate, the one or more first semiconductor dies comprising one or more memory arrays;
bonding one or more second semiconductor dies with a second location of the surface of the substrate, the one or more second semiconductor dies comprising circuitry operable to access the one or more memory arrays via the substrate;
bonding one or more heat transfer components to a surface of the one or more second semiconductor dies opposite the substrate; and
forming a mold compound material over the one or more heat transfer components and the one or more second semiconductor dies on the surface of the substrate, wherein a surface of the one or more heat transfer components opposite the one or more second semiconductor dies is exposed via an opening in the mold compound material.

21. The method of claim 20, wherein forming the mold compound material comprises:
forming the mold compound material over the surface of the one or more heat transfer components opposite the one or more second semiconductor dies; and
exposing the surface of the one or more heat transfer components opposite the one or more second semiconductor dies based at least in part on removing a portion of the mold compound material over the second location of the surface of the substrate to form the opening.

22. The method of claim 20, wherein a surface of the one or more heat transfer components opposite the one or more second semiconductor dies is coplanar with a surface of the mold compound material.

23. The method of claim 20, wherein bonding the one or more heat transfer components with the surface of the one or more second semiconductor dies comprises:
bonding a layer of a thermal interface material or, a die attach film, or both with the surface of the one or more second semiconductor dies; and
bonding a layer of a spacer material with the layer of the thermal interface material, the die attach film, or both.

24. The method of claim 23, wherein the spacer material comprises aluminum, copper, graphite, magnesium, or any combination thereof.

25. The method of claim 20, wherein the mold compound material is formed around one or more sides of the one or more first semiconductor dies and around one or more sides of the one or more second semiconductor dies.

26. The method of claim 20, wherein at least a portion of the one or more heat transfer components extends beyond the one or more second semiconductor dies along one or more directions over the substrate.

27. The method of claim 20, wherein the one or more heat transfer components are configured to support a heat dissipation path from the one or more second semiconductor dies through an opening of the mold compound material.

28. The method of claim 20, wherein:
the one or more memory arrays comprise one or more NAND memory arrays; and
the one or more second semiconductor dies comprise processing circuitry operable to access the one or more NAND memory arrays.
